(19) United States
(12) Patent Application Publication
(10) Pub. No.: US 2002/0181615 A1
(43) Pub. Date: Dec. 5, 2002

(54) Frequency estimator for use in a receiver of packetised data, the receiver and a method of reception

(76) Inventors: Alexandr Kuzminskiy, Swindon (GB); Carlo Luschi, Oxfordshire (GB); Paul Edward Strauch, Gloucester (GB)

Correspondence Address: Docket Administrator (Rm.3J-219), Lucent Technologies Inc., 101 Crawfords Corner Road, Holmdel, NJ, 07733-3030, US

(21) Appl. No.: 10/119,518

(22) Filed: Apr. 10, 2002

(30) Foreign Application Priority Data
Apr. 30, 2001 (GB) 0110537.8

(51) Int. Cl. H04L 27/06; H03H 7/40

(52) U.S. Cl. 375/316; 375/231

(57) ABSTRACT

A frequency estimator is provided for use in a receiver of packetized data. The frequency estimator determines the signal frequency error (\hat{ƒ}o) with which a data packet has been received. It does this by relating data (gn) representative of some symbols to decisions (Sn) on those symbols. These symbols include not only training symbols (Nt) but also some information symbols (Nadd).

### CROSS REFERENCE TO RELATED APPLICATION

This application claims priority of Great Britain Application No. 0110537.8 filed on Apr. 30, 2001.

### BACKGROUND OF THE INVENTION

I. Field of the Invention

The present invention relates to communications, and more particularly to a frequency estimator.

II. Description of the Related Art

Data transmission through frequency and time selective fading channels in TDMA systems, for example those channels where fading due to multipath propagation causes attenuation on a frequency dependent basis, requires fast and efficient signal processing techniques. Some of the TDMA standards, e.g. IS-136, define transmission systems where channel tracking with adaptive equalizers is necessary in order to satisfy performance requirements in terms of permitted Bit or Block Error Rates (BER or BLER)). Other standards, such as GSM or EDGE, define short-burst systems, which potentially allow for burst-by-burst based off-line processing.

As is well known, adaptive filters (equalisers) are used in telecommunication networks to compensate for multipath interference. Signals reflect from buildings, hills and high sided vehicles, and so can take various paths between a transmitter and receiver. Channel equalisation is often performed by estimating the signal transfer properties of the transmission medium (eg. by determining the channel impulse response) and then processing the received signal in order to compensate for the estimated distortion. Alternatively, as is the case of linear or decision feedback least-squares (LS) equalizers, the receiver estimate directly the equalizer parameters (filter coefficients) (see, e.g., S. Haykin, “Adaptive Filter Theory”. Upper Saddle River, N.J.: Prentice Hall, 1996).

Parameter estimation usually relies on a sequence of known data, or training sequence, sent as part of a data packet. The receiver detects the sequence and knowing what symbol pattern it is intended to represent, is able to compensate for the multipath most likely to have produced the received signal.

In known mobile radio networks, i.e. those having mobile subscribers, propagation delays can vary from frame-to-frame to such an extent that complete retraining of the equaliser is necessary before demodulation of each newly received data packet. An example of such a system is that based on the Enhanced Data Rates for GSM Evolution (EDGE) standard.

There are a number of problems to be solved for equalization purposes in the EDGE system. One important practical issue is the Automatic Frequency Correction (AFC) of carrier frequency offset resulting from inaccuracies and/or instabilities of the transmit and receive local oscillators. As outlined in CR: Frequency Compensation Requirements for EDGE Receivers”, ETSI SMG2, Tdoc 268/99, Paris, August 1999), once timing and carrier synchronization has been established by using the transmission of a dedicated burst at communication set-up, the presence of a residual frequency offset often impairs the receiver performance and its capability to provide the required link quality.

Frequency correction techniques often assume that the equivalent channel impulse response at the output of the matched filter is Nyquist. Frequency estimation algorithms have been described in S. Kay, “A Fast and Accurate Single Frequency Estimator”, IEEE Trans. Acoust., Speech, Signal Processing, vol. ASSP-37, pp. 1987-1990, December 1989, and in M. P. Fitz, “Planar Filtered Techniques for Burst Mode Carrier Synchronization”, in Proc IEEE Globecom '91, Phoenix, Ariz., USA, December 1991 and in M. Luise and R. Reggianini, “Carrier Frequency Recovery in All-Digital Modems for Burst-Mode Transmissions”, IEEE Trans. Commun., vol. COM-43, pp. 1169-1178, February/March/April 1995, (see also U. Mengali and A. N. D'Andrea, Synchronization Techniques for Digital Receivers, New York: Plenum Press 1997). In the presence of intersymbol interference at the output of the receive filter, the above methods are known to be applied to the reconstructed training sequence of the prior art off-line equaliser as shown in FIG. 1; or to the output of the channel equalizer in closed-loop schemes with a phase-locked loop (PLL) as described in Y. Shimakazi, T. Nakai, S. Ono, and N. Kondoh. “A Decision Feedback Equalizer with a Frequency Offset Compensating Circuit for Digital Cellular Radio”, in Proc. IEEE Veh. Tech. Conf., 1992, pp. 596-599.

Unfortunately, in known systems, due to the limited amount of available training data, single burst training-based frequency estimation is often not effective because there is insufficient data on which to train. In addition to channel noise affecting the frequency estimator, the known offline equaliser shown is FIG. 1 suffers from the use of a noisy training-based channel estimate. On the other hand, in modem wireless systems employing burst frequency hopping, the accuracy of the frequency estimator needs to be maintained when the frequency offset does not remain approximately constant even over a few successive bursts, which precludes the possibility of usefully averaging the noise over many bursts. Thus, the known solution in FIG. 1 has the disadvantage of causing a performance degradation.

To explain this further, FIG. 2 shows the TDMA slot format of the EDGE system. The symbol duration is Tₛ=3.69 μs. The training and tail symbols are binary and information symbols are drawn from an 8-PSK constellation. The system requirements are defined in the GSM standard for a wide range of propagation conditions, e.g. the Signal-to-Noise Ratio (SNR) is specified for the sensitivity tests from about 11 dB (modulation coding scheme MCS-5, STATIC channel of the GSM Standard) to 31 dB (MCS-9, TU50 channel of the GSM Standard). A random frequency offset of fₒ=±100 Hz is specified in the GSM Standard for successive bursts. An offset of ±200 Hz is often considered. One can see that these system parameters lead to the inequality

fₒ<<1/T (1)

It is known that under condition (1) synchronization before frequency correction is possible. However, known training-based techniques would not be satisfactory. The reason for this is that only Nₜ=26 training symbols are available for frequency offset estimation in each burst and conventional averaging over a number of bursts cannot be used for frequency estimation because of the random offset for every burst. As explained in the Mengali and D'Andrea reference mentioned above the Modified Cramer-Rao Bound (MCRB)

$$M C R B = \frac{3}{2 {π}^{2} {T}_{s}^{2} {N}_{t}^{3} S N R} \qquad ( 2 )$$

where SNR is signal-to-noise ratio shows that the potential standard frequency deviation for the considered application varies from 225 Hz at low SNR to 25 Hz at high SNR. The actual error may be much higher because of imperfections, such as non-stationary propagation conditions and non-ideal equalization. This means that as AFC with training-based frequency estimation cannot be effective for the low-rate modulation coding schemes and therefore performance degradation would occur. On the other hand, an AFC based on pre-estimated data of the whole burst is also not appropriate. Even in the ideal case the angular shift at the edges of the burst is close to the angular distance between the symbols in the alphabet, e.g. θ=2πfₒTₛN≈π/4, when fₒ=200 Hz and N=142. This means that in the non-ideal case estimation errors can be expected at the edges of the burst.

Other known approaches are also not suitable. For example, equalization and frequency estimation techniques based on an estimate of the channel impulse response are often not effective because of the limited amount of training data and possible difficulty in accurately estimating the statistics of the channel disturbance.

### SUMMARY OF THE INVENTION

The present invention provides a frequency estimator for use in a receiver of packetized data, the frequency estimator determining the signal frequency error (f₀) with which a data packet has been received by relating data (gₙ) representative of training symbols and some information symbols to decisions (Sₙ) on those symbols.

Preferably, the data (gₙ) representative of the training symbols and some information symbols are soft data. The term soft data indicates data before a decision is made as to which symbol it represents. It is either the output of a detector or the received signal itself.

Preferably a measure of the error of the frequency estimator using Nt +Nadd symbols at a predetermined signal to noise ratio must be less than about the frequency error to be estimated (fo), where Nt is the number of training symbols in a data packet and Nadd is the number of additional symbols of the packet used for frequency estimators. Preferably the measure of error is the modified Cramer-Rao Bound (MCRB).

Preferably the phase shift caused by a frequency offset error over the Nt+Nadd symbols must be less than half the phase shift between adjacent symbol constellation points.

The present invention also provides an automatic frequency corrector for use in a receiver of packetized data comprising the frequency estimator, and a receiver comprising the same.

The present invention also provides a receiver of packetized data comprising a buffer for received signals, a first detector operative to provide the signals (gₙ) representative of and decisions (Sₙ) on the training symbols and Nadd information symbols, the automatic frequency corrector, and a second detector operative to determine received symbols from the frequency corrected received signals.

The present invention also provides a method of reception of packetized data, comprising the step of determining the signal frequency with which the data packet has been sent by relating data (gₙ) representative of training symbols and some information symbols with decisions (Sₙ) on those symbols.

### BRIEF DESCRIPTION OF THE DRAWINGS

A preferred embodiment of the present invention will now be described by way of example. The present invention will be better understood from reading the following description of non-limiting embodiments, with reference to the attached drawings, wherein below:

FIG. 1 is a schematic block diagram of a conventional equaliser (prior art);

FIG. 2 is a diagram illustrating the known TDMA slot format for the EDGE system;

FIG. 3 is a schematic block diagram of an equaliser according to the present invention;

FIG. 4 is a further schematic block diagram illustrating the equaliser shown in FIG. 3, for comparison with FIG. 1;

FIG. 5a is a diagram illustrating a first possible position for the estimated symbols of stage 3 as shown in FIG. 4 within the TDMA slot format shown in FIG. 3, while

FIG. 5b is a diagram illustrating a second possible position for the estimated symbols at stage 3 as shown in FIG. 4 within the TDMA slot format shown in FIG. 3;

FIG. 6 is a graph showing standard deviation of the estimated frequency over 400 bursts of data for a variable offset frequency and with the additional 24 symbols being used for frequency estimation as shown in FIG. 5a and FIG. 5b respectively (for comparison, data where no information symbols are used and all 116 symbols are used are also shown); and

FIG. 7 is a graph of estimated Block Error Rate (BLER) against signal to noise ratio is shown for a decision feedback equaliser using the extra 24 information symbols for automatic frequency connection for the TU5\acute{Ø} scenario with frequency hopping and using the various standard modulation coding schemes MCS5 to MCS9 known for EDGE Systems (for comparison maximum BLER for the SNR permitted by these coding schemes are also shown).

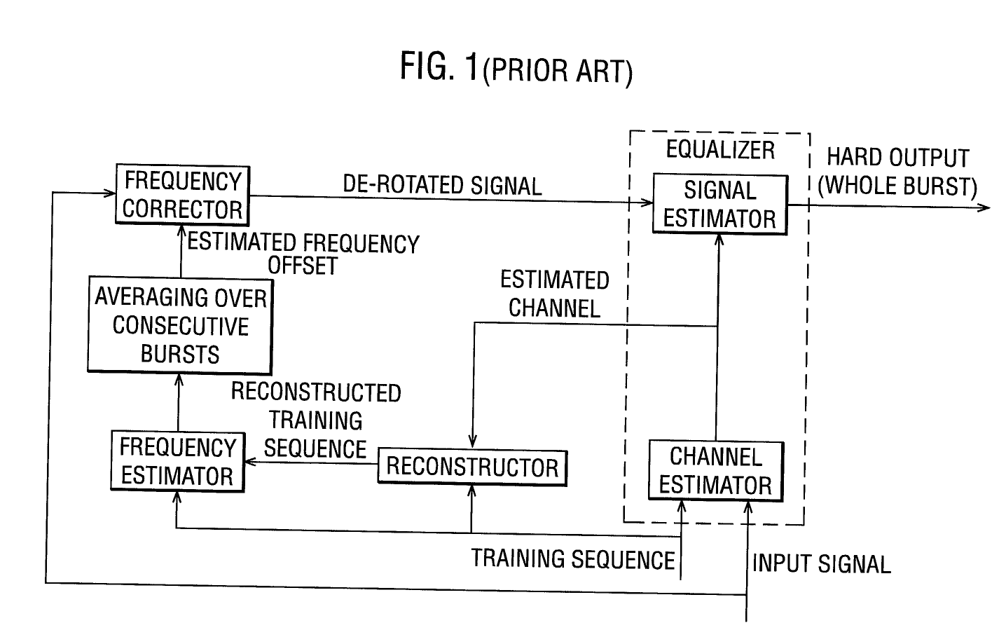

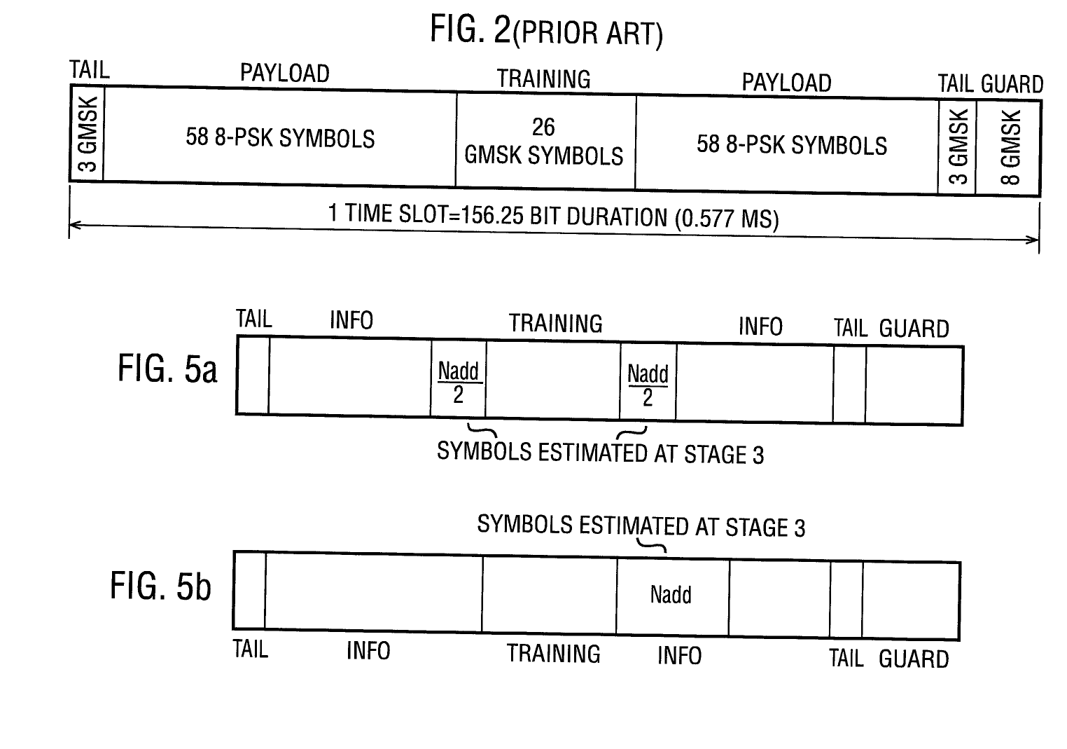

### DETAILED DESCRIPTION

Basically, it was felt that an off-line automatic frequency correction (AFC) for EDGE should be based on frequency estimation over the training sequence plus a restricted number of estimated information symbols. Taking into account the complexity restrictions, it was felt that the required number N_{add} of additional symbols ought to satisfy the following conditions:

MCRB(Nₜ+N_{add})|_{EsNo}_{ₘᵢₙ}<ƒ₀, (3)

θ(Nₜ+N_{add})|_{ƒ}_{₀}<π/8, (4)

Q_{AFC}<Q_{EQ}, (5)

where the reasonable assumption is made that the complexity Q of the AFC has to be lower than the complexity of the equalizer itself. Complexity Q is a measure of the number of operations required to implement a process as is known in the art. Equation (2) can be used in (3). Expressions for the quantities θ nd Q are given below, θ being the angular shift over the time interval used to provide a frequency estimate.

The Off-Line Decision Feedback Equaliser with Automatic Frequency Correction

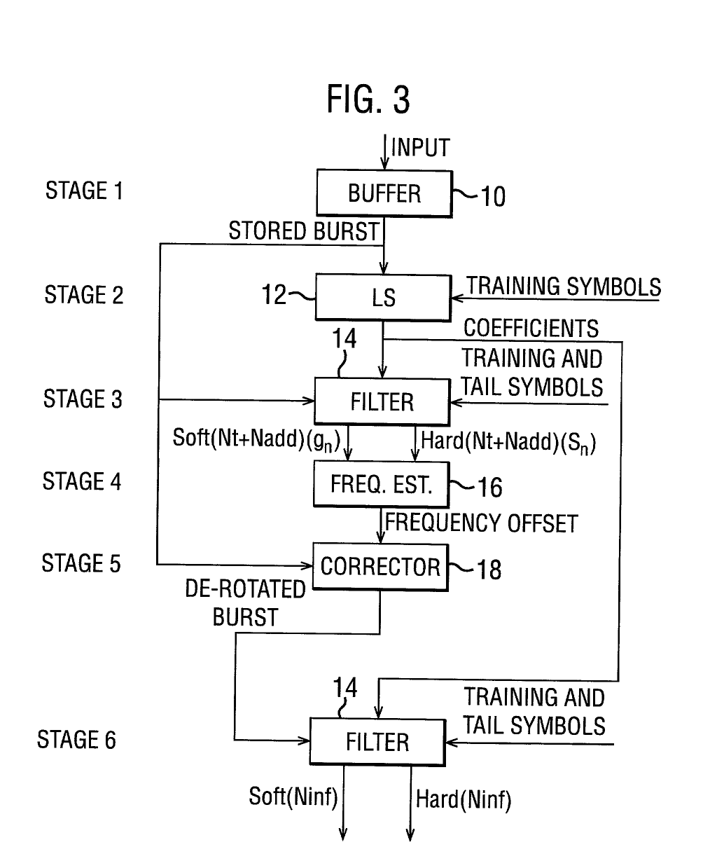

The structure of a preferred off-line equaliser with Automatic Frequency Correction (AFC) for the EDGE system is shown in FIG. 3. A whole burst of data (156 samples) is stored in the buffer block 10.

The synchronization problem is solved separately because of condition(1). We also assume that the position of the training sequence inside the stored burst is known. A nonlinear filter 14 with Decision Feedback (DF) is adjusted by means of the Least Square (LS) estimator 12. The filter 14 at Stage 3 is used to calculate Nₜ+N_{add} output samples for the frequency estimator block 16. The estimated frequency offset is used in the corrector 18 to de-rotate the stored burst. Then, at Stage 6 the de-rotated burst is used as an input signal for the same filter 14 as at Stage 3 to calculate the estimates of the information symbols for the decoder.

The detailed description of the operation of the equaliser is as follows.

A symbol spaced Decision Feedback (DF) FIR filter 14 is used which follows

yₙ=A*Xₙ+B*\tilde{Y}, (6)

where xₙ=rₙe^{j(2πf}ₒTₛn+φ) is the output signal of the buffer block 10, rₙ is the original received signal without frequency offset, φ is an unknown angular shift; X^{T}ₙ={xₙ+d, . . . , x(n+d−L_{f+}I)} is the (L_{f}×1)-vector of input signals, d is a time shift which allows using the tail symbols, \tilde{Y}ₙ={\tilde{y}n−1, . . . , \tilde{y}n−L_{b}} is the (L_{b}×1)-vector of feedback signals, where \tilde{y}ₙ=sₖ at the training interval and \tilde{y}ₙ=ø^{(y}ₙ) otherwise, s_{k, k=}I . . . Nₜ is the training sequence, ø ( ) is the soft decision on the symbols W^{T}={A^{T}B^{T}} and

ZT ={X T YT}

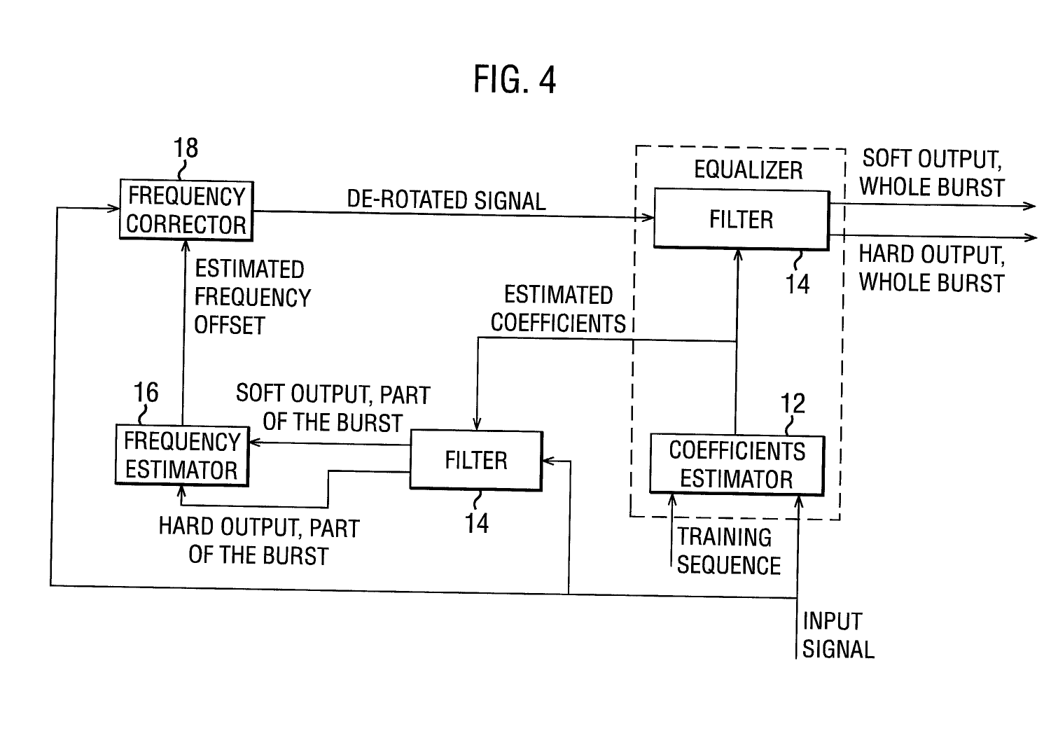

are the (L×1) total vectors of coefficients and signals, L=L_{f}+L_{b} is the total number of adjustable coefficients. yₙ and the hard decisions (projections to the alphabet) ŷₙ are used as the output signals of the FILTER at Stages 3 and 6 of the equaliser shown in FIG. 4.

At Stage 6 estimates of the N_{inf}=116 information symbols are calculated starting from the tail symbols as initializations for the DF. The complexity (the number of complex multiplications) of this stage is Q_{FILTER} (N_{inf})=N_{inf}L. The estimation of Nₜ+N_{add} symbols at Stage 3 in FIG. 4 is implemented by either of the two approaches shown in FIG. 5 leading to different expressions for θ and Q_{AFC} in (4) and (5). The first implementation which is shown in FIG. 5a has the lowest angular shift in the ideal case

θ=2πfₒT(Nₜ+N_{add})/2, (7)

but it is more complicated because all information symbols in the left payload were to be estimated to use the initialization from the tail symbols. The complexity of Stage 3 in this case is

Q_{FILTER}(Nₜ+N_{add})=((N_{inf}+N_{add})/2+Nₜ).L. (8)

In the second case shown in FIG. 5b the corresponding formulas are as follows

θ=2πfₒT(Nₜ/2+N_{add}), (9)

Q_{FILTER}(Nₜ+N_{add})=(Nₜ+N_{add}).L. (10)

We assume that soft decisions and projections to the alphabet can be implemented by means of a look-up table, the complexity of which is not taken into account in the above formulas.

The Last Square Estimator 12

The standard regularized estimator of the DFE weight vector W, which minimizes the LS criterion

$$\hat{W} = a r g {min}_{W} ( {\sum }_{Training} \vert {s}_{k} - {W}^{*} {X}_{n} {\vert}^{2} + δ {W}^{*} W ) \qquad ( 11 )$$

is described by the following equations

Ŵ=(\hat{R}+δI)⁻¹\hat{P}, (12)

$$\begin{matrix}\hat{R} = {\sum }_{Training} {Z}_{n} {Z}_{n}^{*} , & ( 13 ) \\ \hat{P} = {\sum }_{Training} {s}_{k}^{*} {Z}_{n} , & ( 14 )\end{matrix}$$

where δ is a regularization coefficient.

The complexity of this operation is

Q_{LS}=L³+NₜL(L/2+2). (15)

Frequency Estimator 16

The frequency estimation method is based on the model of the received signal at the filter output 14 (without intersymbol interference) as soft data (gₙ) where

gₙ=sₙe^{j(2πƒ}^{₀}^{T}^{ₛ}^{n+Φ}^{₀}⁾+vₙ, (16)

where sₙ=1 . . . N is the transmitted data and vₙ is white Gaussian noise. In the PSK modulation case the following signal can be formed

u_{n=g}ₙsₙ*=e^{j(2πƒ}^{₀}^{Tn+Φ}^{₀}⁾+vₙ, (17)

Then, the frequency estimation can be calculated as

$$\begin{matrix}\hat{f} = \frac{1}{π ( {N}_{av} + 1 ) T} arg \{ {\sum }_{m = 1}^{{N}_{a v}} G ( m ) \} , & ( 18 ) \\ G ( m ) = \frac{1}{N - m} {\sum }_{l = m}^{N - 1} u ( l ) {u ( l - m )}^{*} , 1 \leq m \leq {N}_{av} , & ( 19 )\end{matrix}$$

where Nₐᵥ=N/2 is normally selected.

We apply the estimator (equation 18) in the frequency estimator block 16 in FIG. 3 assuming that gₖ=yₙ and sₖ=ŷₙ, k=1 . . . (Nₜ+N_{add}) for n from the corresponding interval (see FIG. 5). Taking into account that yₙ is found according to the LS criterion (equation 11) after substitution of (equation 16) into (equation 1 1) in place of yₙ=Ŵ*Xₙ we obtain

φₒ=−2πfₒTn_{center}, (20)

where n_{center} is the time index corresponding to the center of the training interval.

The complexity of this stage is

Q_{FE}=(Nₜ+N_{add})²−(Nₜ+N_{add})(Nₜ+N_{add}+1)/2. (21)

Corrector 18

Given the values of estimated frequency offset fₒ and φₒ we perform the following de-rotation of the stored burst of data

rₙ=xₙe^{-j(2π\hat{ƒ}}^{₀}^{Tn+Φ}^{₀}⁾, n=1 . . . 156. (22)

The complexity of this operation is

Q_{CORR}=156. (23)

equations (8), (9), (15), (21), (23) lead to the following estimations of the complexity of the off-line DFE with AFC:

Q_{EQ}=Q_{LS}+Q_{FILTER}(N_{inf}), (24)

Q_{AFC}=Q_{FILTER}(Nₜ+N_{add})+Q_{FE}+Q_{CORR}. (25)

Now we can select the value of N_{add} which satisfies conditions (3)-(5) for the given fₒ and L=L_{f}+L_{b}. We consider fₒ=±200 Hz, L_{f}=5 and L_{b}=2. One can see that according to equations (3) to (5) there is a wide range of possible values of N_{add} even for additional symbols placed around the training interval (FIG. 5a, equations (7), (8)). As the useful number of extra symbols to use in automatic frequency connection, we select N_{add}=24, which corresponds to

$$\begin{matrix}\frac{M C R B ( {N}_{t} + {N}_{a d d} ) \vert 11 dB}{200 Hz} \approx 0.4 & ( 26 ) \\ \frac{Θ ( {N}_{t} + {N}_{a d d} ) {\vert}_{200 Hz}}{π / 8} \approx 0.3 & ( 27 ) \\ \frac{{Q}_{A F C}}{{Q}_{E Q}} \approx 0.7 & ( 28 )\end{matrix}$$

### EXAMPLES USING INFORMATION SYMBOLS FOR AUTOMATIC FREQUENCY CONNECTION

Assuming an EDGE telecommunications system in line with the appropriate ETSI specifications for the GSM standard, namely “Digital cellular telecommunications systems (Phase 2+). Radio transmission and reception (GSM 05.05 version 8.4.0 Release 1999), ETSI EN 300 910 v8.4.0 (2000-05)”, and base station receive filters with an A/D output noise of 5\acute{Ø}dB and random frequency offset, and the following equaliser parameter values: L_{f}=6, L_{b}=2, the following performance results were determined:

### Example 1

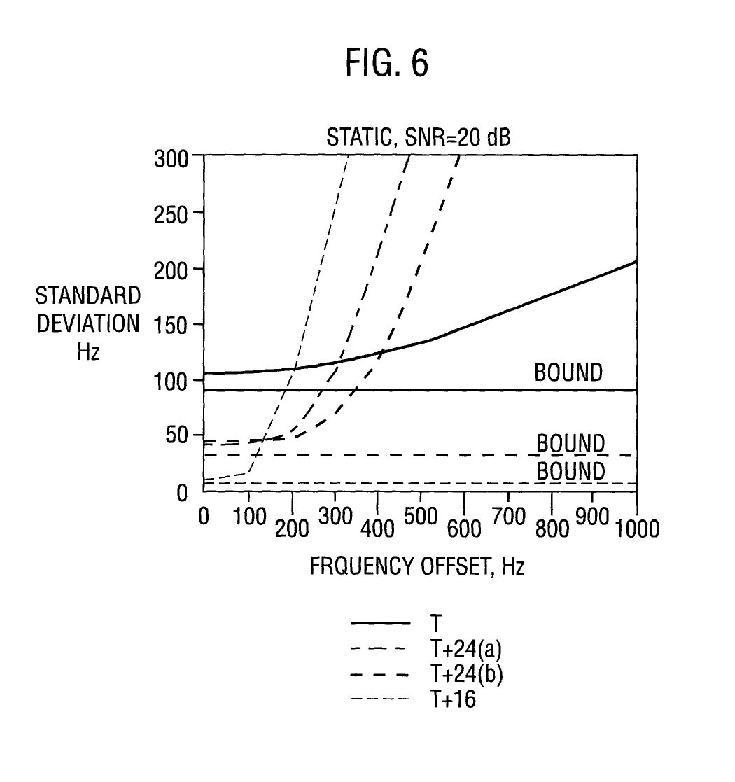

The standard deviation of the estimated frequency over 400 bursts of data for static propagation conditions is presented in FIG. 6 for variable offset fₒ and different values of N_{add}: N_{add}=24 (T+24(a) and T+24(b) for the schemes shown in FIGS. 5a,b accordingly, and also, for comparison, N_{add}=\hat{Ø} (i.e. only the training symbols T are used for AFC) N_{add}=116 i.e. (T+116) symbols are used for AFC. One can see that for low frequency offsets the estimation errors are close to the theoretical lower limits “bounds” in all cases. As expected the applicability of the frequency estimation method depends on the value of N_{add} and positions of the information symbols estimated at Stage 3 which is shown in FIG. 3.

### Example 2

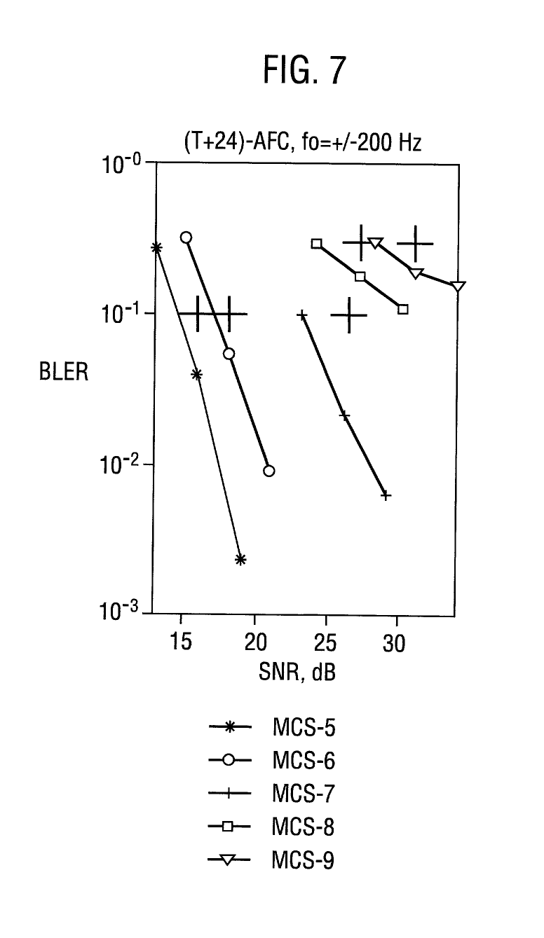

The estimated total Block Error Rate (BLER) and Bit Error Rate (BER) over 2000 blocks (8000 bursts) for the standards MCS-5 . . . 9 in the TU50 propagation scenario with Frequency Hopping (FH) are shown in FIG. 7 for the proposed AFC with N_{add}=24 (FIG. 5a). A random frequency offset of ±200 Hz is used. The required values of the BLER for the EDGE handset are indicated by the crosses assuming 10 dB total noise figure.

FIG. 7 demonstrates that all requirements can be met for N_{add}=24. It is important to emphasize that the complexity of the AFC is still lower than the complexity of the equalizer (see equation 28) which is approximately 3000 complex multiplications per one burst.

The preferred system has advantages of:

Off-line frequency correction and equalization for channels with frequency selective fading without channel estimation.

Allowing a flexible choice of the number and position of training-like symbols, which can be designed depending on the particular cost/performance requirements.

Low complexity: off-line processing with limited amount of data, and single computation of the equalizer coefficients.

Robustness: the processor is not based on channel estimation, and does not rely on a time average over more than one burst.

Flexibility: cost and performance depending on the choice of the number and position of training-like symbols.

Performance: robust performance is achieved in interference-limited scenarios.

While the particular invention has been described with reference to illustrative embodiments, this description is not meant to be construed in a limiting sense. It is understood that although the present invention has been described, various modifications of the illustrative embodiments, as well as additional embodiments of the invention, will be apparent to one of ordinary skill in the art upon reference to this description without departing from the spirit of the invention, as recited in the claims appended hereto. Consequently, the method, system and portions thereof and of the described method and system may be implemented in different locations, such as the wireless unit, the base station, a base station controller, a mobile switching center and/or a radar system. Moreover, processing circuitry required to implement and use the described system may be implemented in application specific integrated circuits, software-driven processing circuitry, firmware, programmable logic devices, hardware, discrete components or arrangements of the above components as would be understood by one of ordinary skill in the art with the benefit of this disclosure. Those skilled in the art will readily recognize that these and various other modifications, arrangements and methods can be made to the present invention without strictly following the exemplary applications illustrated and described herein and without departing from the spirit and scope of the present invention It is therefore contemplated that the appended claims will cover any such modifications or embodiments as fall within the true scope of the invention.

1. A frequency estimator for use in a receiver of packetized data, the frequency estimator determining the signal frequency error with which a data packet has been received by relating data representative of training symbols and some information symbols to decisions on those symbols.

2. The frequency estimator of claim 1, wherein the data representative of training symbols are soft data.

3. The frequency estimator of claim 1, wherein a measure of the error of the frequency estimator using Nt+Nadd symbols at a predetermined signal to noise ratio must be less than about the frequency error to be estimated, where Nt is the number of training symbols in a data packet and Nadd is the number of additional symbols of the packet used for frequency estimation.

4. The frequency estimator of claim 1, wherein the phase-shift caused by a frequency offset error over the Nt+Nadd symbols must be less than half the phase shift between adjacent symbol constellation points.

5. The frequency estimator of claim 4, wherein the phase shift is π/4.

6. The frequency estimator of claim 1, wherein about 20% of the information symbols of a packet are used for frequency estimation.

7. The frequency estimator of claim 1, wherein which the number of information symbols used for frequency training is about 24.

8. The frequency estimator of claim 1, further comprising a receiver of packetized data for providing an estimated frequency offset and correction means cooperative to correct signals representative of received symbols by the estimated frequency offset.

9. The frequency estimator of claim 8, wherein the receiver of packetized data comprises a frequency corrector.

10. The frequency estimator of claim 8, the receiver of packetized data comprising: a buffer for received signals; a first detector operative to provide the signals representative of and decisions on the training symbols and Nadd information symbols; an automatic frequency corrector; and a second detector operative to determine received symbols from the frequency corrected received signals.

11. The frequency estimator of claim 10, wherein at least one of the first detector and the second detector is realized by an equalizer.

12. The frequency estimator of claim 10, wherein the first and second detectors are realized by a single equalizer.

13. The frequency estimator of claim 12, wherein the values of filter coefficients after training are reapplied in a subsequent step of equalization of the frequency connected received signal to determine the symbols of the packet.

14. A method of receiving packetized data comprising: determining the signal frequency error with which the data packet has been received by relating data representative of training symbols and some information symbols with decisions on those symbols.
